(19) United States
(12) Patent Application Publication
(10) Pub. No.: US 2015/0036081 A1
(43) Pub. Date: Feb. 5, 2015

(54) POLARIZER AND DISPLAY PANEL HAVING THE SAME

(71) Applicant: SAMSUNG DISPLAY CO., LTD., Yongin-City (KR)

(72) Inventors: BEONG-HUN BEON, Hwaseong-si (KR); DAE-WON KIM, Suwon-si (KR); JI-HOON KIM, Hwaseong-si (KR); SEUNG-BEOM PARK, Hwaseong-si (KR); SANG-GU LEE, Hwaseong-si (KR); SEUNG-HEE LEE, Hwaseong-si (KR); KYUNG-HWAN JEON, Hwaseong-si (KR)

(73) Assignee: SAMSUNG DISPLAY CO., LTD., Yongin-City (KR)

(21) Appl. No.: 14/186,350

(22) Filed: Feb. 21, 2014

(30) Foreign Application Priority Data
Jul. 30, 2013 (KR) 10-2013-0090113

(51) Int. Cl. G02F 1/1335; H01L 51/52; G02B 5/30

(52) U.S. Cl. CPC G02F 1/133528; G02B 5/3025; H01L 51/5293
USPC 349/96; 359/352; 257/40

(57) ABSTRACT

A polarizer includes a base substrate, a polarization layer adhered to the base substrate and configured to polarize light incident from the base substrate, an infrared ray blocking layer disposed on the polarization layer and a buffer layer having a refractive index smaller than a refractive index of the infrared ray blocking layer.

### CROSS-REFERENCE TO RELATED APPLICATIONS

This application claims priority to Korean Patent Application No. 10-2013-0090113, filed on Jul. 30, 2013, the disclosure of which is hereby incorporated by reference herein in its entirety.

### 1. TECHNICAL FIELD

Example embodiments of the invention relate to a polarizer and a display panel having the polarizer.

More particularly, example embodiments of the present invention relate to a polarizer and a display panel having the polarizer capable of minimizing the effect from external light.

### 2. DISCUSSION OF THE RELATED ART

Recently, a liquid display apparatus having light weight and small size has been manufactured. A cathode ray tube (CRT) display apparatus has been used due to its performance and competitive price. However, the CRT display apparatus may have difficulties with regard to size or portability. Therefore, the liquid display apparatus has been highly regarded due to its small size, light weight and low-power-consumption.

In the liquid display apparatus, a voltage is applied to a specific molecular arrangement of liquid crystals to change the molecular arrangement of the liquid crystals. The liquid display apparatus displays an image using changes in optical property (for example, birefringence, rotatory polarization, dichroism and light scattering) of a liquid crystal cell according to the changes of the molecular arrangement of the liquid crystals.

The liquid display apparatus includes a polarizing plate to control an array of the molecular arrangement of the liquid crystals. A typical polarizing plate passes light which is in parallel with a transmission axis, and absorbs light which is perpendicular with the transmission axis. The typical polarizing plate absorbs some of light from a light source. Thus, the efficiency of the liquid display apparatus may be decreased.

Meanwhile, when the liquid crystal display apparatus is used outside, an external light such as, for example, infrared light of the sun may reach inside of the liquid crystal display apparatus, so that the liquid crystal cell may be damaged by the external light to thereby increase the temperature inside of the display apparatus.

### SUMMARY

Example embodiments of the invention provide a polarizer capable of increasing light efficiency and minimizing the effect from external light.

According to an example embodiment of the invention, a polarizer includes a base substrate, a polarization layer adhered to the base substrate and configured to polarize light incident from the base substrate, an infrared ray blocking layer disposed on the polarization layer and a buffer layer having a refractive index smaller than a refractive index of the infrared ray blocking layer.

In an example embodiment, the infrared ray blocking layer may include polyethylene naphthalate, polyethylene terephthalate or polybutylene-2,6-napthalate.

In an example embodiment, the infrared ray blocking layer may include aluminum(Al), gold(Au), silver(Ag), copper(Cu), chromium(Cr), iron(Fe), nickel(Ni), vanadium(V) or titanium(Ti).

In an example embodiment, an optical thickness of the buffer layer may be about 200 nm to about 500 nm.

In an example embodiment, the buffer layer may include a polyacrylate, a polymethylmethacrylate, a butylacrylate, a polyurethane, an epoxy resin or a polyvinylalcohol.

In an example embodiment, the polarization layer includes a compensation film including a triacetyl cellulose, a cyclo olefin polymer or a polymethyl methacrylate and having a refractive index anisotropy, a polarization film including a poly vinyl alcohol, and a base film configured to support the polarizer.

In an example embodiment, the buffer layer has a refractive index between a refractive index of the polarization layer and the refractive index of the infrared ray blocking layer, and the polarizer is configured to reflect an infrared ray having a wavelength of from about 800 nm to about 2000 nm.

According to an example embodiment of the invention, a display panel includes a first substrate, a second substrate opposing to the first substrate, a display element and a polarizer adhered to the first substrate and including an infrared ray blocking layer, a buffer layer having a smaller refractive index than a refractive index of the infrared ray blocking layer, and a polarization layer configured to polarize light incident from the display element.

In an example embodiment, the infrared ray blocking layer includes polyethylene naphthalate, polyethylene terephthalate or polybutylene-2,6-napthalate.

In an example embodiment, the infrared ray blocking layer may include aluminum(Al), gold(Au), silver(Ag), copper(Cu), chromium(Cr), iron(Fe), nickel(Ni), vanadium(V) and titanium(Ti).

In an example embodiment, the buffer layer has a refractive index between a refractive index of the polarization layer and the refractive index of the infrared ray blocking layer, and the polarizer is configured to reflect an infrared ray having a wavelength which is from about 800 nm to about 2000 nm.

In an example embodiment, an optical thickness of the buffer layer may be about 200 nm to about 500 nm.

In an example embodiment, the buffer layer may include a polyacrylate, a polymethylmethacrylate, a butylacrylate, a polyurethane, an epoxy resin or a polyvinylalcohol.

In an example embodiment, the polarization layer includes a compensation film including a triacetyl cellulose, a cyclo olefin polymer or a polymethyl methacrylate and having a refractive index anisotropy, a polarization film including a poly vinyl alcohol, and a base film configured to support the polarizer.

In an example embodiment, the polarizer may be disposed on a first surface of the first substrate and the display element may be disposed on a second surface of the first substrate which is opposite to the first surface of the first substrate.

In an example embodiment, the polarization layer further includes a plurality of metal patterns disposed on a surface of the buffer layer, and the metal patterns are spaced apart from one another.

In an example embodiment, the polarizer may be disposed on a surface of the first substrate and the display element may be disposed on the polarizer.

In an example embodiment, a pressure sensitive adhesive may be disposed between the first substrate and the polarizer, and the pressure sensitive includes an acrylic resin, a rubber resin, a urethane resin, a silicon resin or a polyvinyl ether resin.

In an example embodiment, the display element includes a liquid crystal layer or an organic light emitting layer.

In an example embodiment, the first substrate includes a thin film transistor and the second substrate includes a color filter configured to provide color to light incident from the display element.

In accordance with an example embodiment, a polarizer is provided. The polarizer includes a base substrate, a polarization layer adhered to an upper surface of the base substrate by a pressure sensitive adhesive and configured to polarize light incident from the base substrate, a buffer layer disposed on an upper surface of the polarization layer, and including a polyacrylate, a polymethylmethacrylate, a butylacrylate, a polyurethane, an epoxy resin and a polyvinylalcohol, an infrared ray blocking layer disposed on an upper surface of the buffer layer. The infrared ray blocking layer has a refractive index greater than a refractive index of the buffer layer.

In addition, the polarizer further includes a coating layer disposed on an upper surface of the infrared ray blocking layer.

According to example embodiments of the present invention, the polarizer includes an infrared ray blocking layer having a relatively high refractive index and a buffer layer having a relatively low refractive index, so that the polarizer may pass and may reflect light having a specific wavelength range. An infrared ray emitted from inside of the display panel may be increased and an infrared ray incident from outside may be reflected more. Thus, an increase in the average temperature inside of the display panel may be prevented, so that reliability of the display apparatus may be increased.

### BRIEF DESCRIPTION OF THE DRAWINGS

Example embodiments of the invention can be understood in more detail from the following detailed description taken in conjunction with the accompanying drawings, in which:

FIG. 1 is a cross-sectional view illustrating a polarizer in accordance with an example embodiment of the invention;

FIG. 2 is a plan view illustrating a display panel in accordance with an example embodiment of the invention.

FIG. 3 is a cross-sectional view taken along the line I-I′ in FIG. 2;

FIG. 3 is a cross-sectional view taken along the line I-I′ in FIG. 2;

FIG. 4 is a cross-sectional view illustrating the polarizer of the display panel in FIG. 2;

FIG. 5 is a cross-sectional view illustrating an example of the polarizer of the display panel in FIG. 2;

FIG. 6 is a cross-sectional view illustrating an example of the polarizer of the display panel of FIG. 2;

FIG. 7 is a cross-sectional view illustrating an example of the polarizer of the display panel of FIG. 2;

FIG. 8 is a cross-sectional view illustrating an example of the polarizer of the display panel of FIG. 2;

FIG. 9 is a cross-sectional view illustrating a display panel in accordance with an example embodiment of the invention;

FIG. 10 is a cross-sectional view illustrating the polarizer of the display panel of FIG. 9;

FIG. 11 is a graph illustrating a relationship between a transmittance of a conventional polarizer and a transmittance of the polarizer according to an example embodiment of the present invention of FIG. 4; and

FIG. 12 is a graph illustrating a relationship between the temperature of a conventional typical polarizer and the temperature of the polarizer according to an example embodiment of the present invention of FIG. 4.

### DETAILED DESCRIPTION OF EXAMPLE EMBODIMENTS

Hereinafter, example embodiments of the invention will be explained in detail with reference to the accompanying drawings.

In the drawings, the thickness of layers, films, panels, regions, etc., may be exaggerated for clarity. Like reference numerals designate like elements throughout the specification. It will be understood that when an element such as a layer, film, region, or substrate is referred to as being “on” another element, it can be directly on the other element or intervening elements may also be present.

As used herein, the singular forms, “a”, “an”, and “the” are intended to include plural forms as well, unless the context clearly indicates otherwise.

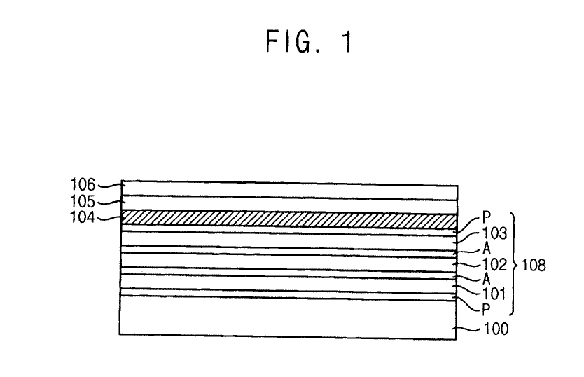

FIG. 1 is a cross-sectional view illustrating a polarizer in accordance with an example embodiment of the invention.

Referring to FIG. 1, a polarizer includes, for example, a base substrate 100, a polarization layer 108, a buffer layer 104, an infrared ray blocking layer 105 and a coating layer 106.

The base substrate 100 may include, for example, a material having relatively excellent transmittance, thermal resistance and chemical resistance. For example, the base substrate 100 may include a glass substrate, a quartz substrate, or a plastic substrate. Further, in an embodiment, the base substrate 100 may be, for example, a flexible substrate. Suitable materials for the flexible substrate include, for example, polyethylenenaphthalate, polyethylene terephthalate, polyacryl, polyimide, polyethersulfone, polyvinyl chloride. The base substrate 100 may include, for example, a display panel including a liquid crystal layer or an organic light emitting layer.

The polarization layer 108 includes, for example, a compensation film 101, a polarization film 102 and a base film 103. The polarization layer 108 may polarize light incident from the base substrate 100.

The compensation film 101 is disposed on the base substrate 100. The compensation film 101 may have refractive index anisotropy to compensate for light-leakage in a display panel. The compensation film 101 is adhered to the base substrate 100 by, for example, a pressure sensitive adhesive P.

For example, the compensation film 101 may include a triacetyl cellulose, a cyclo olefin polymer, a polymethyl methacrylate, etc.

For example, the pressure sensitive adhesive P may include an acrylic resin, a rubber resin, a urethane resin, a silicon resin, a polyvinylether resin, etc. The acrylic resin may include, for example, a (meth) acrylic ester base polymer such as a (meth) acrylic butyl acrylate, a (meth) acrylic ethyl acrylate, a (meth) acrylic isooctyl, a (meth) acrylic 2-ethylhexyl, etc.

The polarization film 102 is disposed on the compensation film 101. The polarization film 102 is adhered to the compensation film 101 by, for example, an adhesive A.

For example, the adhesive A may include a water solvent type adhesive, an organic solvent type adhesive, a hot melt type adhesive, a non solvent type adhesive or an ultraviolet curable resin. For example, the water solvent type adhesive may include polyvinyl alcohol or a two component type urethane emulsion adhesive. The organic solvent type adhesive may include, for example, a two component type urethane adhesive. The non solvent type adhesive may include, for example, a mono fluid type urethane adhesive.

For example, the ultraviolet curable resin may include an oligomer, a monomer, a photopolymerization initiator, an additive agent, etc. The oligomer may include, for example, a polyester acrylate, an epoxy acrylate, a urethane acrylate, a polyether acrylate or a silicon acrylate. The monomer may include a mono functional monomer or a multi functional monomer.

The photopolymerization initiator may include, for example, a benzoin ether or amine. The additive agent may include, for example, a tackifier, a filler or polymerization inhibitor.

A polyvinyl alcohol film is, for example, stretched, aligned in the stretched direction of the polyvinyl alcohol film, and then, iodine molecular or two colors dye molecular is absorbed in the polyvinyl alcohol film to form the polarization film 102. A polarization degree may be determined according to an amount of dyeing or stretching.

The base film 103 is disposed on the polarization film 102. The base film 103 is adhered to the polarization film 102 by, for example, the adhesive A. The base film 103 serves as a supporting layer of the polarizer and has transparent property, low water resistance, high adhesive property, etc.

For example, the base film 103 may include a triacetyl cellulose or a polymethyl methacrylate. For example, a refractive index of light passing through the compensation film 101, the polarization film 102 and the base film 103 to a second direction D2 may be about 1.00 to about 1.48.

The buffer layer 104 is disposed on the base film 103. The buffer layer 104 may include, for example, a polyacrylate, a polymethylmethacrylate, a butylacrylate, a polyurethane, an epoxy resin or a polyvinylalcohol. A refractive index of the buffer layer 104 is, for example, greater than a refractive index of the base film 103. The buffer layer 104 partially reflects light incident from the base substrate 100 in a first direction D1. The buffer layer 104 partially transmits light incident from the base substrate 100 in the second direction D2. The first direction D1 is opposite to the second direction D2 in a plan view. For example, a refractive index of light passing through the buffer layer 104 may be about 1.48 to about 1.74. An optical thickness of the buffer layer 104 may be, for example, about 200 nm to about 500 nm.

The buffer layer 104 is adhered to the base film 103 by, for example, a pressure sensitive adhesive P.

In an example embodiment, the buffer layer 104 may include, for example, scattered particles such as beads or a micro pattern such as fine protrusions.

Alternatively, the buffer layer 104 may be formed to have, for example, a multi-layered structure. The multi-layered buffer layer 104 has a relatively high refractive index, which is increased gradually toward the coating layer 106.

The infrared ray blocking layer 105 is disposed on the buffer layer 104. For example, the infrared ray blocking layer 105 may include polyethylene naphthalate, polyethylene terephthalate or polybutylene-2,6-napthalate. For example, the infrared ray blocking layer 105 may include aluminum (Al), gold (Au), silver (Ag), copper (Cu), chromium (Cr), iron (Fe), nickel (Ni), vanadium (V) or titanium (Ti). For example, in an embodiment, the infrared ray blocking layer 105 includes vanadium dioxide (VO₂) or titanium dioxide (TiO₂). A refractive index of the infrared ray blocking layer 105 may be, for example, about 1.74. Thus, the infrared ray blocking layer 105 has a relatively high refractive index, so that an infrared ray of, for example, a wavelength of about 800 nm to about 2000 nm incident from outside, may be reflected.

The coating layer 106 is disposed on the infrared ray blocking layer 105. The coating layer 106 has a high hardness and prevents a reflection. For example, the coating layer 106 may include an anti glare film, an anti reflective film, a low reflective film or a hard coating film.

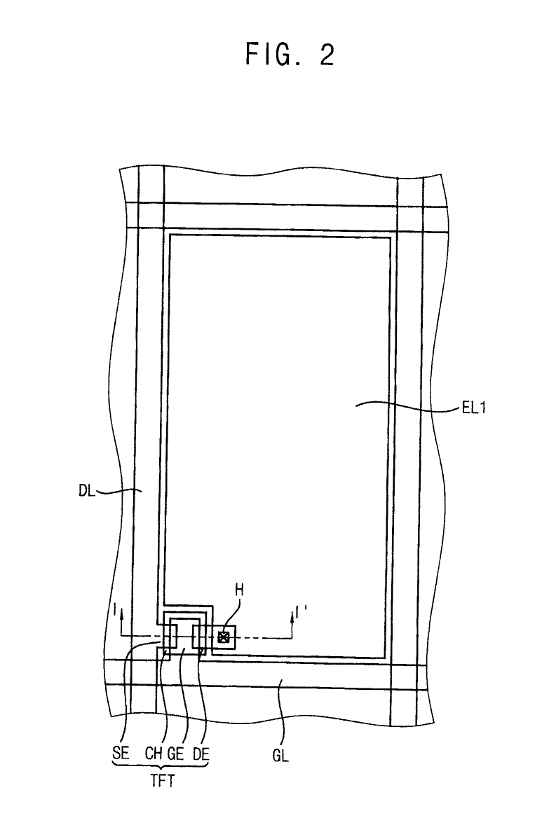

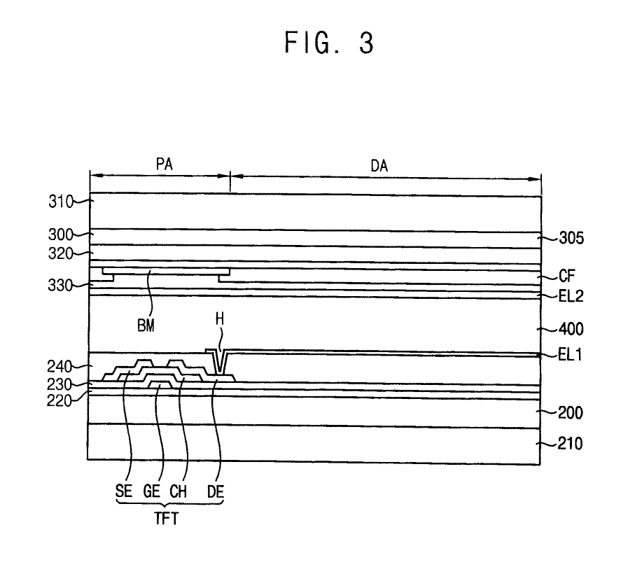

FIG. 2 is a plan view illustrating a display panel in accordance with an example embodiment of the invention. FIG. 3 is a cross-sectional view taken along the line I-I′ in FIG. 2.

Referring to FIGS. 2 and 3, a display panel includes, for example, a first substrate, a second substrate facing the first substrate, a liquid crystal layer 400 disposed between the first substrate and the second substrate and polarizers 210, 310 each disposed on the first substrate or the second substrate.

The first substrate includes, for example, a first base substrate 200, a first polarizer 210, a first passivation layer 220, a thin film transistor TFT, a first insulation layer 230, a second insulation layer 240 and a first electrode EL1.

The first base substrate 200 may include, for example, a material which has a relatively high transmittance, thermal resistance, and chemical resistance. For example, the first base substrate 200 may include a glass substrate, a quartz substrate, or a plastic substrate. Further, in an embodiment, the first base substrate 200 may be, for example, a flexible substrate. Suitable materials for the flexible substrate include, for example, polyethylenenaphthalate, polyethylene terephthalate, polyacryl, polyimide, polyethersulfone, polyvinyl chloride, etc.

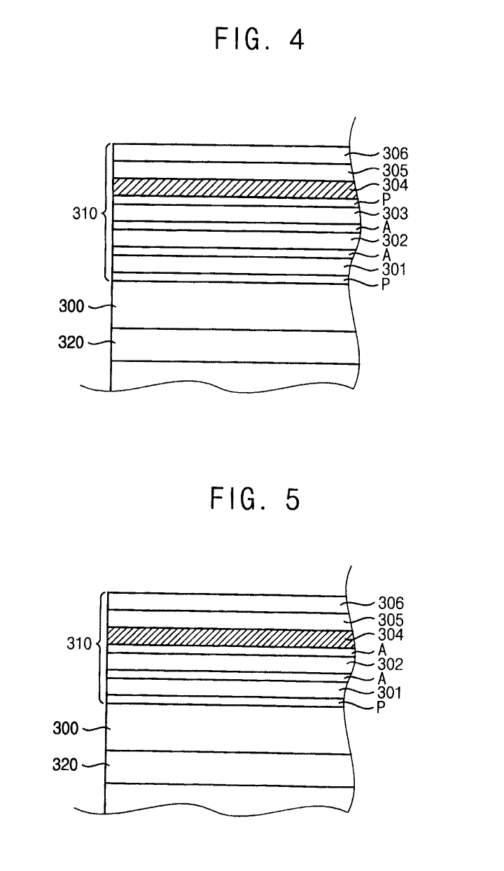

The polarizer may include, for example, the first polarizer 210 and a second polarizer 310. Detailed explanations about the first polarizer 210 and the second polarizer 310 will be described in detail with reference to FIG. 4.

The first passivation layer 220 is disposed on the first base substrate 200. The first passivation layer 220 may have, for example, a film shape. The first passivation layer 220 protects the first base substrate 200.

A gate line GL and a gate electrode GE are disposed on the first passivation layer 220. The gate line GL and the gate electrode GE are formed in, for example, a peripheral area PA. The gate electrode GE is electrically connected to the gate line GL. For example, in an embodiment, the gate electrode GE and the gate line GL may each be formed of aluminum (Al), copper (Cu), molybdenum (Mo), titanium (Ti), nickel (Ni), tungsten (W), gold (Au), palladium (Pd), platinum (Pt), chromium (Cr), neodymium (Nd), zinc (Zn), ruthenium (Ru), cobalt (Co) and any mixtures or alloys thereof.

The first insulation layer 230 is disposed on the first passivation layer 220 on which the gate electrode GE and the gate line GL are disposed. The first insulation layer 230 may include, for example, an inorganic material such as silicon oxide (SiOx), silicon nitride (SiNx) and silicon oxynitride (SiONx).

A channel layer CH is disposed on the first insulation layer 230 to overlap the gate electrode GE. The channel layer CH may include, for example, a semiconductor layer of amorphous silicon (a-Si:H) and an ohmic contact layer of, for example, n+ amorphous silicon (n+ a-Si:H). In addition, the channel layer CH may include, for example, an oxide semiconductor. The oxide semiconductor may include, for example, an amorphous oxide including indium (In), zinc (Zn), gallium (Ga), tin (Sn) and hafnium (Hf). For example, the oxide semiconductor may include an amorphous oxide having indium (In), zinc (Zn) and gallium (Ga), or an amorphous oxide having indium (In), zinc (Zn) and hafnium (Hf). The oxide semiconductor may include, for example, an oxide such as indium zinc oxide (InZnO), indium gallium oxide (InGaO), indium tin oxide (InSnO), zinc tin oxide (ZnSnO), gallium tin oxide (GaSnO) and gallium zinc oxide (GaZnO).

A data line DL crossing the gate line GL is disposed on the first insulation layer 230.

A source electrode SE and a drain electrode DE are disposed on the channel layer CH. The source electrode SE is electrically connected to the data line DL, and spaced apart from the drain electrode DE. The drain electrode DE is electrically connected to the first electrode EL1 through a contact hole H. For example, in an embodiment, the source electrode SE and the drain electrode DE may each be formed of aluminum (Al), copper (Cu), molybdenum (Mo), titanium (Ti), nickel (Ni), tungsten (W), gold (Au), palladium (Pd), platinum (Pt), chromium (Cr), neodymium (Nd), zinc (Zn), ruthenium (Ru), cobalt (Co) and any mixtures or alloys thereof.

The gate electrode GE, the source electrode SE, the drain electrode DE and the channel layer CH form the thin film transistor TFT in the peripheral area PA.

The second insulation layer 240 is disposed on the thin film transistor TFT and the first insulation layer 230 on which the data line DL is formed. The second insulation layer 240 may include, for example, an inorganic material such as silicon oxide (SiOx), silicon nitride (SiNx) and silicon oxynitride (SiONx). In addition, the second insulation layer 240 may include, for example, an organic insulating material having relatively low permittivity. In addition, the second insulation layer 240 may have, for example, a double layer structure of inorganic and organic insulating layers. The second insulation layer 240 has the contact hole H exposing a portion of the drain electrode DE.

The first electrode EL1 is disposed on the second insulation layer 240. The first electrode EL1 is formed corresponding to the display area DA. The first electrode EL1 is electrically connected to the drain electrode DE of the thin film transistor TFT through the contact hole H. The first electrode EL1 may include, for example, a transparent conductive material, such as indium tin oxide (ITO), indium zinc oxide (IZO), gallium oxide (GaOx), aluminum doped zinc oxide (AZO), cadmium zinc oxide (CZO), indium gallium zinc oxide (IGZO), etc. In an embodiment, the first electrode EL1 may include, for example, a slit pattern having a plurality of openings.

The second substrate includes, for example, a second base substrate 300, a second polarizing plate 310, a second passivation layer 320, a black matrix BM, a color filter CF, an over-coating layer 330 and a second electrode EL2.

The second base substrate 300 may include a material which has a relatively high transmittance, thermal resistance, and chemical resistance. For example, the second base substrate 300 may include a glass substrate, a quartz substrate, or a plastic substrate. Further, in an embodiment, the second base substrate 300 may be, for example, a flexible substrate. Suitable materials for the flexible substrate include, for example, polyethylenenaphthalate, polyethylene terephthalate, polyacryl, polyimide, polyethersulfone, polyvinyl chloride, etc

The second passivation layer 320 is disposed on the second base substrate 300. The second passivation layer 320 may have, for example, a film shape. The second passivation layer 320 protects the second base substrate 300.

The black matrix BM is disposed on the second passivation layer 320. The black matrix BM is disposed in the peripheral area PA, and blocks light. Thus, the black matrix BM overlaps the data line DL, the gate line GL, and the thin film transistor TFT.

The color filter CF is disposed in a display area DA and on the second passivation layer 320 on which the black matrix BM is formed. The color filter CF supplies colors to the light passing through the liquid crystal layer 400. The color filter CF may include, for example, a red color filter, a green color filter and blue color filter. The color filter CF corresponds to the pixel area. The color filters CF adjacent to each other may have, for example, different colors. The color filter CF may be overlapped with an adjacent color filter CF in a boundary of the pixel area. In addition, the color filter CF may be spaced apart from an adjacent color filter CF in the boundary of the pixel area.

The over-coating layer 330 is disposed on the color filter CF and the black matrix BM. The over-coating layer 330 planarizes the color filter CF, protects the color filter CF, and insulates the color filter CF. The over-coating layer 330 may include, for example, an acrylic-epoxy material. In addition, the over-coating layer 330 may also include other materials such as a polyimide, a polyamide, a benzocyclobutene (BCB), and a phenolic resin.

The second electrode EL2 is disposed on the over-coating layer 330. The second electrode EL2 may correspond to both the display area DA and the peripheral area PA. In addition, the second electrode EL2 may correspond to the display area DA The second electrode EL2 may include a transparent conductive material, such as, for example, indium tin oxide (ITO), indium zinc oxide (IZO), gallium oxide (GaOx), aluminum doped zinc oxide (AZO), cadmium zinc oxide (CZO), indium gallium zinc oxide (IGZO), etc.

The liquid crystal layer 400 is disposed between the first substrate and the second substrate. The liquid crystal layer 400 includes liquid crystal molecules having optical anisotropy. The liquid crystal molecules are driven by an electric field, so that an image is displayed by passing or blocking light through the liquid crystal layer 400.

FIG. 4 is a cross-sectional view illustrating the polarizer of the display panel in FIG. 2.

The polarizer may include, for example, the first polarizer 210 and the second polarizer 310. The first polarizer 210 is substantially the same as the second polarizer 310. Thus, any further detailed descriptions concerning the first polarizer 210 will be omitted.

Referring to FIG. 4, the second polarizer 310 is disposed on a surface of the second base substrate 300. The second polarizer 310 includes, for example, a polarization layer, a buffer layer 304, an infrared ray blocking layer 305 and a coating layer 306.

The polarization layer includes, for example, a compensation film 301, a polarization film 302 and a base film 303.

The compensation film 301 is disposed on the second base substrate 300. The compensation film 301 is adhered to second base substrate 300 by, for example, a pressure sensitive adhesive P.

For example, the compensation film 301 may include a triacetyl cellulose, a cyclo olefin polymer or a polymethyl methacrylate.

For example, the pressure sensitive adhesive P may include an acrylic resin, a rubber resin, a urethane resin, a silicon resin or a polyvinylether resin. The acrylic resin may include, for example, a (meth) acrylic ester base polymer such as a (meth) acrylic butyl acrylate, a (meth) acrylic ethyl acrylate, a (meth) acrylic isooctyl or a (meth) acrylic 2-ethylhexyl.

The polarization film 302 is disposed on the compensation film 301. The polarization film 302 is adhered to the compensation film 301 by, for example, an adhesive A.

For example, the adhesive A may include a water solvent type adhesive, an organic solvent type adhesive, a hot melt type adhesive, a non solvent type adhesive or an ultraviolet curable resin. For example, the water solvent type adhesive may include a polyvinyl alcohol or a two component type urethane emulsion adhesive. The organic solvent type adhesive may include, for example, a two component type urethane adhesive. The non solvent type adhesive may include, for example, a mono fluid type urethane adhesive.

For example, the ultraviolet curable resin may include an oligomer, a monomer, a photopolymerization initiator, an additive agent, etc. The oligomer may include, for example, a polyester acrylate, an epoxy acrylate, a urethane acrylate, a polyether acrylate or a silicon acrylate. The monomer may include a mono functional monomer or a multi functional monomer.

The photopolymerization initiator may include, for example, a benzoin ether or amine. The additive agent may include, for example, a tackifier, a filler or a polymerization inhibitor.

A polyvinyl alcohol film is, for example, stretched, aligned in the stretched direction of the polyvinyl alcohol film, and then, iodine (I2) molecular or two colors dye molecular is absorbed to the polyvinyl alcohol film to form the polarization film 302. A polarization degree may be determined according to amount of dyeing or stretching.

The base film 303 is disposed on the polarization film 302. The base film 303 is combined with the polarization film 302 by, for example, an adhesive A. The base film 303 serves as a supporting layer of the polarizer and has transparent property, low water resistance, high connection property, etc.

For example, the base film 303 may include a triacetyl cellulose or a polymethyl methacrylate. For example, a refractive index of light passing through the compensation film 301, the polarization film 302, the base film 303 in a second direction D2 may be about 1.00 to about 1.48.

The buffer layer 304 is disposed on the base film 303. For example, the buffer layer 304 may include a polyacrylate, a polymethylmethacrylate, a butylacrylate, a polyurethane, an epoxy resin or a polyvinylalcohol. A refractive index of the buffer layer 304 is, for example, greater than a refractive index of the base film 303. The buffer layer 304 partially reflects light incident from the second base substrate 300. For example, a refractive index of light passing through the buffer layer 304 may be about 1.48 to about 1.74. An optical thickness of the buffer layer 304 may be, for example, about 200 nm to about 500 nm.

The buffer layer 304 is adhered to the base film 303 by, for example, a pressure sensitive adhesive P.

The infrared ray blocking layer 305 is disposed on the buffer layer 304. For example, the infrared ray blocking layer 305 may include polyethylene naphthalate, polyethylene terephthalate or polybutylene-2,6-napthalate. For example, the infrared ray blocking layer 305 may include aluminum (Al), gold (Au), silver (Ag), copper (Cu), chromium (Cr), iron (Fe), nickel (Ni), vanadium (V) or titanium (Ti). For example, in an embodiment, the infrared ray blocking layer 305 includes vanadium dioxide (VO2) or titanium dioxide (TiO2). A refractive index of the infrared ray blocking layer 305 may be, for example, about 1.74. Thus, the infrared ray blocking layer 305 has a high refractive index, so that an infrared ray of wavelength of about 800 nm to about 2000 nm from outside, may be reflected.

The coating layer 306 is disposed on the infrared ray blocking layer 305. The coating layer 306 has a high hardness and prevents a reflection. For example, the coating layer 306 may include an anti glare film, an anti reflective film, a low reflective film or a hard coating film.

FIG. 5 is a cross-sectional view illustrating an example of the polarizer of the display panel in FIG. 2.

The second polarizer 310 is disposed on a surface of the second base substrate 300. The second polarizer 310 includes, for example, a polarization layer, a buffer layer 304, an infrared ray blocking layer 305 and a coating layer 306.

The polarization layer includes, for example, a compensation film 301 and a polarization film 302.

The second polarizer 310 of the present embodiment is substantially the same as the second polarizer 310 of FIG. 4, except that a buffer layer 304 is disposed on a surface of the polarization film 302 without a base film interposed therebetween. Thus, any further detailed descriptions concerning the same elements will be omitted.

The compensation film 301 is disposed on the second base substrate 300 by, for example, the pressure sensitive adhesive P. The polarization film 302 is disposed on the compensation film 301 by, for example, the adhesive A. The buffer layer 304 is disposed on the polarization film 302. For example, the buffer layer 304 may include a polyacrylate, a polymethylmethacrylate, a butylacrylate, a polyurethane, an epoxy resin or a polyvinylalcohol. A refractive index of the buffer layer 304 is, for example, greater than a refractive index of the base film 303. The buffer layer 304 may selectively pass a specific wavelength range of light through the second base substrate 300 to the coating layer 306.

The buffer layer 304 is adhered to the polarization film 302 by, for example, the adhesive A.

For example, a refractive index of light passing through the buffer layer 304 may be about 1.48 to about 1.74. An optical thickness of the buffer layer 304 may be, for example, about 200 nm to about 500 nm. In the present embodiment, the buffer layer 304 instead of a base film protects the polarization film 302. Thus, the cost of manufacturing the display apparatus may be decreased.

The infrared ray blocking layer 305 is disposed on the buffer layer 304. For example, the infrared ray blocking layer 305 may include polyethylene naphthalate, polyethylene terephthalate or polybutylene-2,6-napthalate. For example, the infrared ray blocking layer 305 may include aluminum (Al), gold (Au), silver (Ag), copper (Cu), chromium (Cr), iron (Fe), nickel (Ni), vanadium (V) or titanium (Ti). For example, in an embodiment, the infrared ray blocking layer 305 includes vanadium dioxide (VO2) or titanium dioxide (TiO2). A refractive index of the infrared ray blocking layer 305 may be, for example, about 1.74. Thus, the infrared ray blocking layer 305 has a high refractive index, so that an infrared ray of wavelength of about 800 nm to about 2000 nm from outside, may be reflected.

In addition, the coating layer 306 is disposed on the infrared ray blocking layer 305.

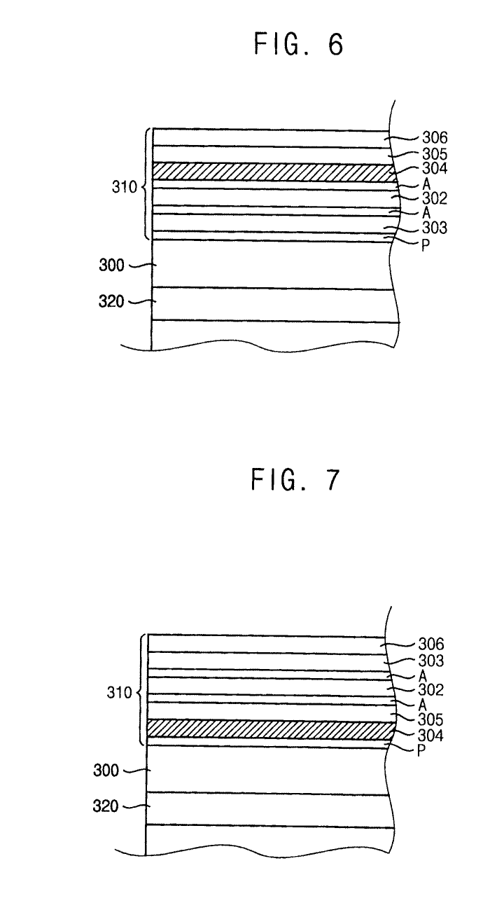

FIG. 6 is a cross-sectional view illustrating an example of the polarizer of the display panel of FIG. 2.

The second polarizer 310 is disposed on the second base substrate 300. The second polarizer 310 includes, for example, a polarization layer, a buffer layer 304, an infrared ray blocking layer 305 and a coating layer 306.

The polarization layer includes, for example, a base film 303 and a polarization film 302.

The second polarizer 310 of the present embodiment is substantially the same as the second polarizer 310 of FIG. 4, except that a base film 303 is disposed on a surface of the second base substrate 300 without a compensation film. Thus, any further detailed descriptions concerning the same elements will be omitted.

The base film 303 is disposed on the second base substrate 300 by, for example, the pressure sensitive adhesive P. The polarization film 302 is disposed on the base film 303 by, for example, the adhesive A.

The buffer layer 304 is disposed on the polarization film 302 by, for example, the adhesive A. For example, the buffer layer 304 may include a polyacrylate, a polymethylmethacrylate, a butylacrylate, a polyurethane, an epoxy resin or a polyvinylalcohol. A refractive index of the buffer layer 304 is, for example, greater than a refractive index of the base film 303. The buffer layer 304 may selectively pass a specific wavelength range of light through the second base substrate 300 to the coating layer 306. For example, a refractive index of passed light from the buffer layer 304 may be about 1.48 to about 1.74. An optical thickness of the buffer layer 304 may be, for example, about 200 nm to about 500 nm. In the present embodiment, the buffer layer 304 instead of a compensation film protects the polarization film 302. Thus, the cost of manufacturing the display apparatus may be decreased.

The infrared ray blocking layer 305 is disposed on the buffer layer 304. For example, the infrared ray blocking layer 305 may include polyethylene naphthalate, polyethylene terephthalate or polybutylene-2,6-napthalate. For example, the infrared ray blocking layer 305 may include aluminum (Al), gold (Au), silver (Ag), copper (Cu), chromium (Cr), iron (Fe), nickel (Ni), vanadium (V) or titanium (Ti). For example, in an embodiment, the infrared ray blocking layer 305 includes vanadium dioxide (VO2) or titanium dioxide (TiO2). A refractive index of the infrared ray blocking layer 305 may be, for example, about 1.74. Thus, the infrared ray blocking layer 305 has a high refractive index, so that an infrared ray of wavelength of about 800 nm to about 2000 nm from outside, may be reflected.

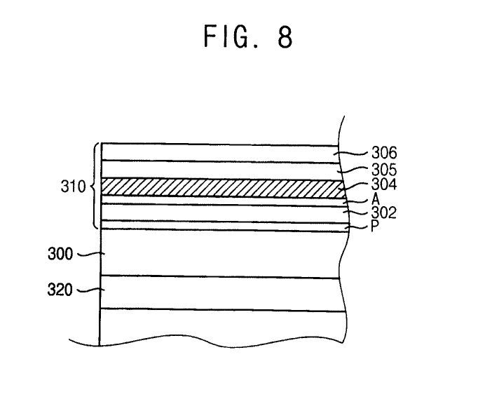

FIG. 7 is a cross-sectional view illustrating an example of the polarizer of the display panel of FIG. 2.

The second polarizer 310 is disposed on the second base substrate 300. The second polarizer 310 includes, for example, a polarization layer, a buffer layer 304, an infrared ray blocking layer 305 and a coating layer 306.

The polarization layer includes, for example, a base film 303 and a polarization film 302.

The second polarizer 310 of the present embodiment is substantially the same as the second polarizer 310 of FIG. 4, except that a buffer layer 304 and an infrared blocking layer 305 are disposed on a surface of the second base substrate 300. Thus, any further detailed descriptions concerning the same elements will be omitted.

The buffer layer 304 is disposed on the second base substrate 300 by, for example, the pressure sensitive adhesive P. For example, the buffer layer 304 may include a polyacrylate, a polymethylmethacrylate, a butylacrylate, a polyurethane, an epoxy resin or a polyvinylalcohol. A refractive index of the buffer layer 304 is, for example, greater than a refractive index of the second base substrate 300. The buffer layer 304 may selectively pass a specific wavelength range of light through the second base substrate 300 to the coating layer 306. For example, a refractive index of passed light from the buffer layer 304 may be about 1.48 to about 1.74. An optical thickness of the buffer layer 304 may be, for example, about 200 nm to about 500 nm.

The infrared ray blocking layer 305 is disposed on the buffer layer 304. For example, the infrared ray blocking layer 305 may include polyethylene naphthalate, polyethylene terephthalate or polybutylene-2,6-napthalate. For example, the infrared ray blocking layer 305 may include aluminum (Al), gold (Au), silver (Ag), copper (Cu), chromium (Cr), iron (Fe), nickel (Ni), vanadium (V) or titanium (Ti). For example, the infrared ray blocking layer 305 includes vanadium dioxide (VO2) or titanium dioxide (TiO2). A refractive index of the infrared ray blocking layer 305 may be, for example, about 1.74. Thus, the infrared ray blocking layer 305 has a high refractive index, so that an infrared ray of wavelength of about 800 nm to about 2000 nm from outside, may be reflected.

The polarization film 302 is disposed on the infrared ray blocking layer 305 by, for example, the adhesive A.

Polyvinyl alcohol film is, for example, stretched, polymer chain is aligned to a stretched direction of the polyvinyl alcohol film, and iodine (I2) molecular or two colors dye molecular is absorbed to the polyvinyl alcohol film to form the polarization film 302. A polarization degree may be determined according to amount of dyeing or stretching.

The base film 303 is disposed on the polarization film 302 by, for example, the adhesive A. The coating layer 306 is disposed on the base film 303.

FIG. 8 is a cross-sectional view illustrating an example of the polarizer of the display panel of FIG. 2.

The second polarizer 310 is disposed on the second base substrate 300. The second polarizer 310 includes, for example, a polarization layer, a buffer layer 304, an infrared ray blocking layer 305 and a coating layer 306. The polarization layer includes, for example, a polarization film 302.

The second polarizer 310 of the present embodiment is substantially the same as the second polarizer 310 of FIG. 4, except that a polarization film 302 is disposed on a surface of the second base substrate 300 without a compensation film and a base film. Thus, any further detailed descriptions concerning the same elements will be omitted.

The polarization film 302 is disposed on the second base substrate 300 by, for example, the pressure sensitive adhesive P.

The buffer layer 304 is disposed on the polarization film 302 by, for example, the adhesive A. For example, the buffer layer 304 may include a polyacrylate, a polymethylmethacrylate, a butylacrylate, a polyurethane, an epoxy resin or a polyvinylalcohol. A refractive index of the buffer layer 304 is, for example, greater than a refractive index of the second base substrate 300. The buffer layer 304 may selectively pass a specific wavelength range of light through the second base substrate 300 to the coating layer 306. For example, a refractive index of passed light from the buffer layer 304 may be about 1.48 to about 1.74. An optical thickness of the buffer layer 304 may be, for example, about 200 nm to about 500 nm. In the present embodiment, the buffer layer 304 instead of a compensation film and a base film protects the polarization film 302. Thus, the cost of manufacturing the display apparatus may be decreased.

The infrared ray blocking layer 305 is disposed on the buffer layer 304. For example, the infrared ray blocking layer 305 may include polyethylene naphthalate, polyethylene terephthalate or polybutylene-2,6-napthalate. For example, the infrared ray blocking layer 305 may include aluminum (Al), gold (Au), silver (Ag), copper (Cu), chromium (Cr), iron (Fe), nickel (Ni), vanadium (V) or titanium (Ti). For example, in an embodiment, the infrared ray blocking layer 305 includes vanadium dioxide (VO2) or titanium dioxide (TiO2). A refractive index of the infrared ray blocking layer 305 may be, for example, about 1.74. Thus, the infrared ray blocking layer 305 has a high refractive index, so that an infrared ray of wavelength of about 800 nm to about 2000 nm from outside, may be reflected.

The coating layer 306 is disposed on the infrared ray blocking layer 305.

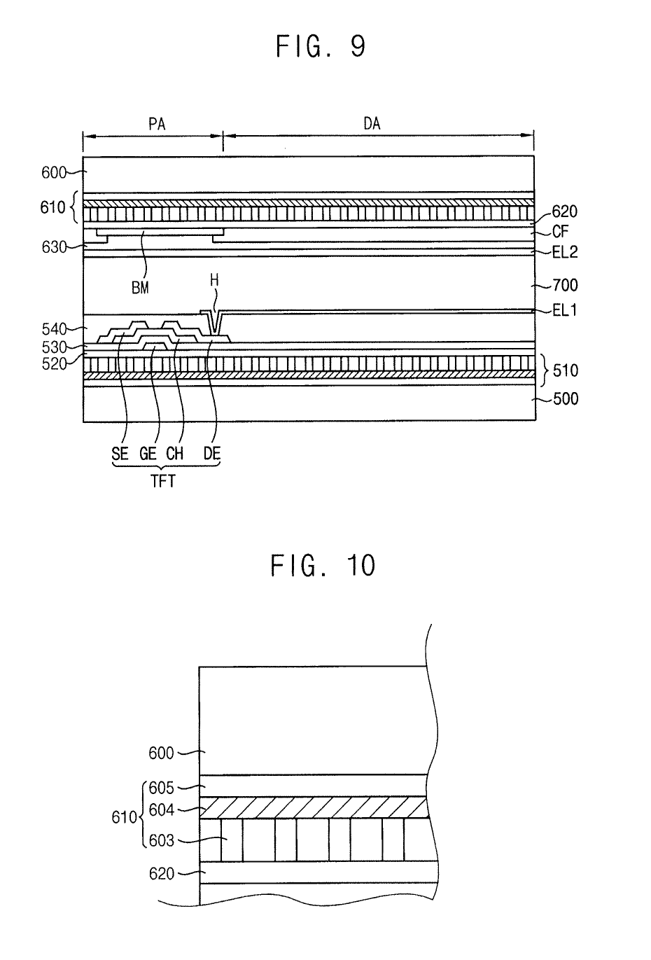

FIG. 9 is a cross-sectional view illustrating a display panel in accordance with an example embodiment of the invention.

Referring to FIG. 9, a display panel includes, for example, a first substrate, a second substrate facing the first substrate, a liquid crystal layer 700 disposed between the first substrate and the second substrate and polarizers each disposed on the first substrate or the second substrate.

The first substrate includes, for example, a first base substrate 500, a first polarizer 510, a first passivation layer 520, a thin film transistor TFT, a first insulation layer 530, a second insulation layer 540 and a first electrode EL1.

The first base substrate 500 may include, for example, a material which has a relatively high transmittance, thermal resistance, and chemical resistance. For example, the first base substrate 500 may include a glass substrate, a quartz substrate, or a plastic substrate. Further, in an embodiment, the first base substrate 500 may be, for example, a flexible substrate. Suitable materials for the flexible substrate include, for example, polyethylenenaphthalate, polyethylene terephthalate, polyacryl, polyimide, polyethersulfone, polyvinyl chloride, etc.

The polarizer may include, for example, the first polarizer 510 and a second polarizer 610. Detailed explanations about the first polarizer 510 and the second polarizer 610 will be described in detail with reference to FIG. 10.

The first passivation layer 520 is disposed on the first polarizer 510. The first passivation layer 520 may have, for example, a film shape. The first passivation layer 520 protects the first polarizer 510.

A gate line GL and a gate electrode GE are disposed on the first passivation layer 520. The gate line GL and the gate electrode GE are formed in the peripheral area PA. The gate electrode GE is electrically connected to the gate line GL.

For example, in an embodiment, the gate electrode GE and the gate line GL may each be formed of aluminum (Al), copper (Cu), molybdenum (Mo), titanium (Ti), nickel (Ni), tungsten (W), gold (Au), palladium (Pd), platinum (Pt), chromium (Cr), neodymium (Nd), zinc (Zn), ruthenium (Ru), cobalt (Co) and any mixtures or alloys thereof.

The first insulation layer 530 is disposed on the first passivation layer 520 on which the gate electrode GE and the gate line GL are disposed. The first insulation layer 530 may include, for example, an inorganic material such as silicon oxide (SiOx), silicon nitride (SiNx) and silicon oxynitride (SiONx).

A channel layer CH is disposed on the first insulation layer 530 to overlap the gate electrode GE. The channel layer CH may include, for example, a semiconductor layer of amorphous silicon (a-Si:H) and an ohmic contact layer of, for example, n+ amorphous silicon (n+ a-Si:H). In addition, the channel layer CH may include, for example, an oxide semiconductor. The oxide semiconductor may include, for example, an amorphous oxide having indium (In), zinc (Zn), gallium (Ga), tin (Sn) and hafnium (Hf). For example, the oxide semiconductor may include an amorphous oxide having indium (In), zinc (Zn) and gallium (Ga), or an amorphous oxide having indium (In), zinc (Zn) and hafnium (Hf). The oxide semiconductor may include, for example, an oxide such as indium zinc oxide (InZnO), indium gallium oxide (InGaO), indium tin oxide (InSnO), zinc tin oxide (ZnSnO), gallium tin oxide (GaSnO) and gallium zinc oxide (GaZnO).

A data line DL crossing the gate line GL is disposed on the first insulation layer 530.

A source electrode SE and a drain electrode DE are disposed on the channel layer CH. The source electrode SE is electrically connected to the data line DL, and spaced apart from the drain electrode DE. The drain electrode DE is electrically connected to the first electrode EU through a contact hole H. For example, in an embodiment, the source electrode SE and the drain electrode DE may each be formed of aluminum (Al), copper (Cu), molybdenum (Mo), titanium (Ti), nickel (Ni), tungsten (W), gold (Au), palladium (Pd), platinum (Pt), chromium (Cr), neodymium (Nd), zinc (Zn), ruthenium (Ru), cobalt (Co) and any mixtures or alloys thereof.

The gate electrode GE, the source electrode SE, the drain electrode DE and the channel layer CH form the thin film transistor TFT in the peripheral area PA.

The second insulation layer 540 is disposed on the thin film transistor TFT and the first insulation layer 530 on which the data line DL is formed. The second insulation layer 540 may include, for example, an inorganic material such as silicon oxide (SiOx), silicon nitride (SiNx) and silicon oxynitride (SiONx). In addition, the second insulation layer 540 may include, for example, an organic insulating material having relatively low permittivity. In addition, the second insulation layer 540 may have, for example, a double layer structure of inorganic and organic insulating layers. The second insulation layer 540 has the contact hole H exposing a portion of the drain electrode DE.

The first electrode EL1 is disposed on the second insulation layer 540. The first electrode EL1 is formed corresponding to the display area DA. The first electrode EL1 is electrically connected to the drain electrode DE of the thin film transistor TFT through the contact hole H. The first electrode EL1 may include, for example, a transparent conductive material, such as indium tin oxide (ITO), indium zinc oxide (IZO), gallium oxide (GaOx), aluminum doped zinc oxide (AZO), cadmium zinc oxide (CZO), indium gallium zinc oxide (IGZO), etc. In an embodiment, the first electrode EL1 may include, for example, a slit pattern having a plurality of openings.

The second substrate includes, for example, a second base substrate 600, a second polarizer 610, a second passivation layer 620, a black matrix BM, a color filter CF, an over-coating layer 630 and a second electrode EL2.

The second base substrate 600 may include, for example, a material which has a relatively high transmittance, thermal resistance, and chemical resistance. For example, the second base substrate 600 may include a glass substrate, a quartz substrate, or a plastic substrate. Further, in an embodiment, the second base substrate 600 may be, for example, a flexible substrate. Suitable materials for the flexible substrate include, for example, polyethylenenaphthalate, polyethylene terephthalate, polyacryl, polyimide, polyethersulfone, polyvinyl chloride, etc.

The second passivation layer 620 is disposed on the second base substrate 600. The second passivation layer 620 may have, for example, a film shape. The second passivation layer 620 protects the second base substrate 600.

The black matrix BM is disposed on the second passivation layer 620. The black matrix BM is disposed in the peripheral area PA, and blocks light. Thus, the black matrix BM overlaps the data line DL, the gate line GL, and the thin film transistor TFT.

The color filter CF is disposed in the display area DA and on the second passivation layer 620 on which the black matrix BM is formed. The color filter CF supplies colors to the light passing through the liquid crystal layer 700. The color filter CF may include, for example, a red color filter, a green color filter and blue color filter. The color filter CF corresponds to the pixel area. The color filters CF adjacent to each other may have, for example, different colors. The color filter CF may be overlapped with an adjacent color filter CF in a boundary of the pixel area. In addition, the color filter CF may be spaced apart from an adjacent color filter CF in the boundary of the pixel area.

The over-coating layer 630 is disposed on the color filter CF and the black matrix BM. The over-coating layer 630 planarizes the color filter CF, protects the color filter CF, and insulates the color filter CF. The over-coating layer 630 may include, for example, an acrylic-epoxy material. In addition, the over-coating layer 630 may also include other materials such as a polyimide, a polyamide, a benzocyclobutene (BCB), and a phenolic resin.

The second electrode EL2 is disposed on the over-coating layer 630. The second electrode EL2 may correspond to both the display area DA and the peripheral area PA. In addition, the second electrode EL2 may correspond to the display area DA The second electrode EL2 may include, for example, a transparent conductive material, such as indium tin oxide (ITO), indium zinc oxide (IZO), gallium oxide (GaOx), aluminum doped zinc oxide (AZO), cadmium zinc oxide (CZO), indium gallium zinc oxide (IGZO), etc.

The liquid crystal layer 700 is disposed between the first substrate and the second substrate. The liquid crystal layer 700 includes liquid crystal molecules having optical anisotropy. The liquid crystal molecules are driven by an electric field, so that an image is displayed by passing or blocking light through the liquid crystal layer 700.

FIG. 10 is a cross-sectional view illustrating the polarizer of the display panel of FIG. 9.

The first polarizer 510 is substantially the same as the second polarizer 610. Thus, any further detailed descriptions concerning the first polarizer will be omitted.

Referring to FIG. 10, the second polarizer 610 is disposed on the second base substrate 600. The second polarizer 610 includes, for example, a plurality of metal patterns 603 spaced apart from one another, a buffer layer 604 and an infrared ray blocking layer 605. A width and a thickness of the metal pattern 603 may range from, for example, about several tens to about several hundreds of nanometers. For example, a width of the metal pattern 603 may be about 50 nm, a gap between the adjacent metal patterns 603 may be about 50 nm, and a thickness of the metal pattern 603 may be about 150 nm. The metal pattern 603 of the polarizer may extend in a direction. The polarizer transmits light which is, for example, incident perpendicular with the extending direction of the metal pattern 603. The polarizer reflects light which is, for example, incident parallel with the extending direction of the metal pattern 603. In an example embodiment, the first polarizer 510 and the second polarizer 610 may be formed corresponding to the display area DA and the peripheral area PA.

The buffer layer 604 is disposed on the metal pattern 603. The buffer layer 604 may include, for example, a polyacrylate, a polymethylmethacrylate, a butylacrylate, a polyurethane, an epoxy resin or a polyvinylalcohol. A refractive index of the buffer layer 604 is, for example, greater than a refractive index of the metal pattern 603. The buffer layer 604 may selectively pass a specific wavelength range of light through the second base substrate 600 to the liquid crystal layer 700. For example, a refractive index of light passing through the buffer layer 604 may be about 1.48 to about 1.74. An optical thickness of the buffer layer 604 may be, for example, about 200 nm to about 500 nm.

The infrared ray blocking layer 605 is disposed on the buffer layer 604. For example, the infrared ray blocking layer 605 may include polyethylene naphthalate, polyethylene terephthalate or polybutylene-2,6-napthalate. For example, the infrared ray blocking layer 605 may include aluminum (Al), gold (Au), silver (Ag), copper (Cu), chromium (Cr), iron (Fe), nickel (Ni), vanadium (V) or titanium (Ti). For example, in an embodiment, the infrared ray blocking layer 305 includes vanadium dioxide (VO2) or titanium dioxide (TiO2). A refractive index of the infrared ray blocking layer 305 may be, for example, about 1.74. Thus, the infrared ray blocking layer 305 has a high refractive index, so that an infrared ray of a wavelength of about 800 nm to about 2000 nm from outside, may be reflected.

In an example embodiment, the buffer layer 604 may be formed as, for example, a multilayer. The multilayered buffer layer 604 has a relatively high refractive index in a direction in which the infrared ray blocking layer 605 is disposed.

In an example embodiment, the polarization layer may include, for example, a film including dyes, a dual brightness enhancement film, a anisotropy refractive index film, etc.

According to an example embodiment of the present invention, the first polarizer 510 and the second polarizer 610 are relatively spaced apart from each other between the liquid crystal layer 700. Thus, the changing of an electrical characteristic of the thin film transistor TFT may be prevented.

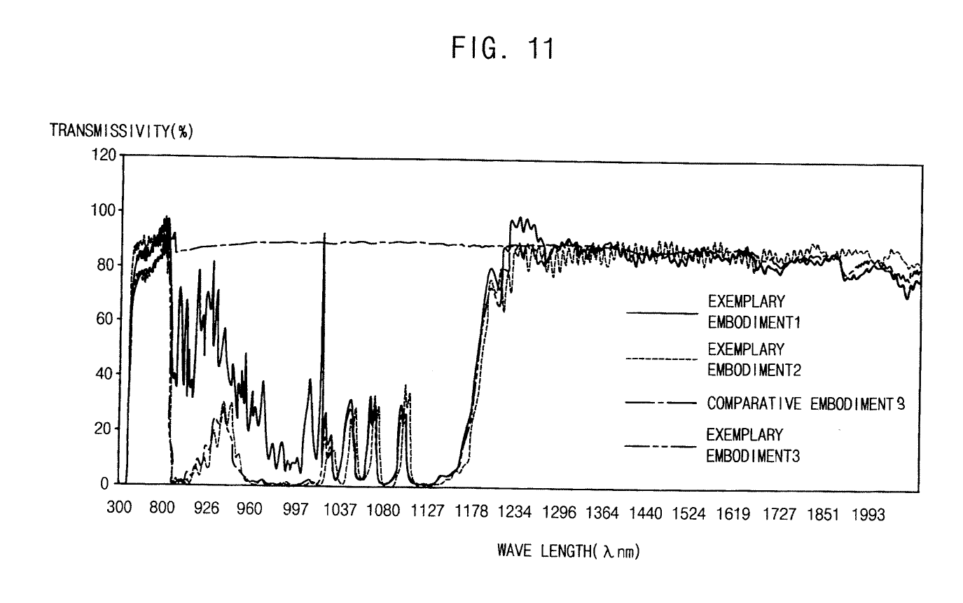

FIG. 11 is a graph illustrating a relationship between a transmittance of a conventional polarizer and a transmittance of the polarizer according to an example embodiment of the present invention of FIG. 4.

Referring to FIG. 11, X axis represents wavelength (λ, nm) and Y axis represents transmissivity (%). Example Embodiment 1 represents transmissivity when solar light passes a polarizer including a buffer layer and an infrared ray blocking layer of FIG. 1 in a second direction D2. Example Embodiment 2 represents transmissivity when solar light passes a polarizer including a buffer layer, an infrared ray blocking layer and a base substrate of FIG. 1. Comparative Embodiment 1 represents transmissivity when solar light passes a conventional polarizer not including a buffer layer and an infrared ray blocking layer in a second direction D2. Example Embodiment 3 represents transmissivity when solar light passes a polarizer including a buffer layer and an infrared ray blocking layer of FIG. 1 in a first direction D1. When comparing the curves of Example Embodiment 1, Example Embodiment 2, Example Embodiment 3 and Comparative Embodiment 1, it can be noted that Example Embodiments 1 to 3 transmit light of about 800 nm to about 1200 nm wavelength more than Comparative Embodiment 1. Thus, an infrared ray emitted from inside may be increased and an infrared ray incident from the outside may be reflected more.

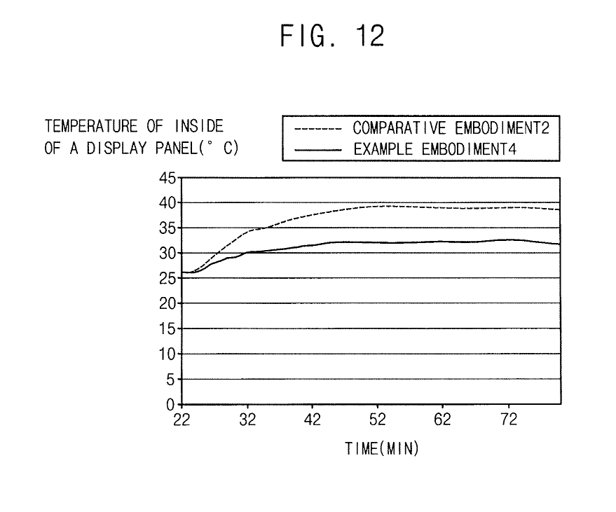

FIG. 12 is a graph illustrating a relationship between the temperature of a conventional typical polarizer and the temperature of the polarizer according to an example embodiment of the present invention of FIG. 4.

Referring to FIG. 12, X axis represents time (min) and Y axis represents a temperature (° C.) of inside of the display panel. Comparative Embodiment 2 represents a temperature of inside of a conventional display panel not including the first polarizer 210 and the second polarizer 310. Example Embodiment 4 represents a temperature of inside of a display panel including the first polarizer 210 and the second polarizer 310 according to an example embodiment of the present invention of FIG. 4.

A temperature of inside of the display panel of Example Embodiment 4 is lower than a temperature of inside of the display panel of Comparative Embodiment 2. Thus, the inner temperature of the display panel may be decreased by the first polarizer 210 and the second polarizer 310. According to example embodiments of the present invention, the polarizer includes an infrared ray blocking layer having a relatively high refractive index and a buffer layer having a relatively low refractive index, so that the polarizer may pass and may reflect light having a specific wavelength range. An infrared ray emitted from inside of the display panel may be increased and an infrared ray incident from outside may be reflected more. Thus, an increase in the average temperature inside of the display panel may be prevented, so that reliability of the display apparatus may be increased.

Having described example embodiments of the present invention, it is further noted that it is readily apparent to those of ordinary skill in the art that various modifications may be made without departing from the spirit and scope of the invention which is defined by the metes and bounds of the appended claims.

What is claimed is:

1. A polarizer comprising:
a base substrate;
a polarization layer adhered to the base substrate and configured to polarize light incident from the base substrate;
an infrared ray blocking layer disposed on the polarization layer; and
a buffer layer having a refractive index smaller than a refractive index of the infrared ray blocking layer.

2. The polarizer of claim 1, wherein the infrared ray blocking layer comprises at least one selected from the group consisting of polyethylene naphthalate, polyethylene terephthalate and polybutylene-2,6-napthalate.

3. The polarizer of claim 1, wherein the infrared ray blocking layer comprises at least one selected from the group consisting of aluminum (Al), gold (Au), silver (Ag), copper (Cu), chromium (Cr), iron (Fe), nickel (Ni), vanadium (V) and titanium (Ti).

4. The polarizer of claim 1, wherein an optical thickness of the buffer layer is about 200 nm to about 500 nm.

5. The polarizer of claim 1, wherein the buffer layer comprises at least one selected from the group consisting of a polyacrylate, a polymethylmethacrylate, a butylacrylate, a polyurethane, an epoxy resin and a polyvinylalcohol.

6. The polarizer of claim 1, wherein the polarization layer comprises
a compensation film comprising a triacetyl cellulose, a cyclo olefin polymer or a polymethyl methacrylate and having a refractive index anisotropy,
a polarization film comprising a poly vinyl alcohol; and
a base film configured to support the polarizer.

7. The polarizer of claim 1, wherein the buffer layer has a refractive index between a refractive index of the polarization layer and the refractive index of the infrared ray blocking layer, and wherein the polarizer is configured to reflect an infrared ray having a wavelength of from about 800 nm to about 2000 nm.

8. A display panel comprising:
a first substrate;
a second substrate opposing the first substrate;
a display element; and
a polarizer adhered to the first substrate and comprising an infrared ray blocking layer, a buffer layer having a smaller refractive index than a refractive index of the infrared ray blocking layer, and a polarization layer configured to polarize light incident from the display element.

9. The display panel of claim 8, wherein the infrared ray blocking layer comprises at least one selected from the group consisting of polyethylene naphthalate, polyethylene terephthalate and polybutylene-2,6-napthalate.

10. The display panel of claim 8, wherein the infrared ray blocking layer comprises at least one selected from the group consisting of aluminum (Al), gold (Au), silver (Ag), copper (Cu), chromium (Cr), iron (Fe), nickel (Ni), vanadium (V) and titanium (Ti).

11. The display panel of claim 8, wherein the buffer layer has a refractive index between a refractive index of the polarization layer and the refractive index of the infrared ray blocking layer, and wherein the polarizer is configured to reflect an infrared ray having a wavelength which is from about 800 nm to about 2000 nm.

12. The display panel of claim 8, wherein an optical thickness of the buffer layer is about 200 nm to about 500 nm.

13. The display panel of claim 8, wherein the buffer layer comprises at least one selected from the group consisting of a polyacrylate, a polymethylmethacrylate, a butylacrylate, a polyurethane, an epoxy resin and a polyvinylalcohol.

14. The display panel of claim 8, wherein the polarization layer comprises
a compensation film comprising a triacetyl cellulose, a cyclo olefin polymer or a polymethyl methacrylate and having a refractive index anisotropy,
a polarization film comprising a poly vinyl alcohol; and
a base film configured to support the polarizer.

15. The display panel of claim 14, wherein the polarizer is disposed on a first surface of the first substrate and the display element is disposed on a second surface of the first substrate which is opposite to the first surface of the first substrate.

16. The display panel of claim 8, wherein the polarization layer further comprises a plurality of metal patterns disposed on a surface of the buffer layer, wherein the metal patterns are spaced apart from one another.

17. The display panel of claim 16, wherein the polarizer is disposed on a surface of the first substrate and the display element is disposed on the polarizer.

18. The display panel of claim 8, wherein a pressure sensitive adhesive is disposed between the first substrate and the polarizer, and wherein the pressure sensitive adhesive comprises at least one selected from the group consisting of an acrylic resin, a rubber resin, a urethane resin, a silicon resin and a polyvinylether resin.

19. The display panel of claim 8, wherein the display element comprises a liquid crystal layer or an organic light emitting layer.

20. The display panel of claim 8, wherein the first substrate comprises a thin film transistor and the second substrate comprises a color filter configured to provide color to light incident from the display element.
